(19) United States
(12) Patent Application Publication
(10) Pub. No.: US 2017/0082669 A1
(43) Pub. Date: Mar. 23, 2017

(54) APPARATUS FOR MEASURING ANTENNA RADIATION PATTERN

(71) Applicant: NATIONAL RADIO RESEARCH AGENCY, Naju-si, Jeollanam-do (KR)

(72) Inventors: Jung Kuy PARK, Icheon-si, Gyeonggi-do (KR); Woo Nyun KIM, Icheon-si, Gyeonggi-do (KR); Byeong Gyu KANG, Seoul (KR); Han Gook YEON, Wonju-si, Gangwon-do (KR)

(73) Assignee: NATIONAL RADIO RESEARCH AGENCY, Naju-si, Jeollanam-do (KR)

(21) Appl. No.: 15/311,176

(22) PCT Filed: May 15, 2015
(86) PCT No.: PCT/KR2015/004909

§ 371 Date: Nov. 14, 2016

(30) Foreign Application Priority Data
May 15, 2014 (KR) 10-2014-0058476

(51) Int. Cl. G01R 29/10; H01Q 1/12; G01B 3/56

(52) U.S. Cl. CPC G01R 29/10; G01B 3/56; H01Q 1/1242

(57) ABSTRACT

An apparatus for measuring an antenna radiation pattern comprises a lower bearing unit; a hollow mast which is installed in the vertical direction; a hollow vertical bar, the length of which is vertically adjustable in a state; a goniometer which is horizontally coupled to the upper part of the vertical bar; a horizontal shaft which is positioned at the upper part of the goniometer; a first mounting unit, the length of which is vertically adjustable in a state; a second mounting unit having a vertical shaft which is coupled to the horizontal shaft by vertically penetrating one end of the horizontal shaft, the second mounting unit being installed on the upper end of the vertical shaft; and a support unit of which one end is coupled to the horizontal shaft and the other end is coupled to the outer periphery of the mast.

### TECHNICAL FIELD

The present invention relates to an apparatus for measuring an antenna radiation pattern and, more particularly, to an apparatus for measuring an antenna radiation pattern that is capable of rotating an antenna at a predetermined angle with respect to the center of the front side of an opening of the antenna through a vertical shaft thereof in an open area test site, an electromagnetic anechoic chamber, etc., thereby measuring the antenna radiation pattern easily and conveniently.

### BACKGROUND ART

Generally, an antenna is a device for radiating or receiving electromagnetic EM energy. An ideal transmission antenna receives electric power from a supply source and radiates the received electric power to a space.

That is, unless the electromagnetic energy is reflected or dispersed through the radiation of the antenna, it is not returned.

However, the antenna actually produces radiating and non-radiating electromagnetic elements. Portion of the non-radiating electromagnetic elements is returned to the supply source, and if not, it becomes a portion of the received electric power dispersed at a resistive load.

The performance of an antenna is described in various ways.

Firstly, the radiation efficiency of an antenna is defined as the ratio of the quantity of electric power received to the antenna to the quantity of electric power radiated by the antenna.

A portion of electric power, which is received to the antenna but is not radiated therefrom, may be dispersed to the form of heat.

Secondly, the directionality of an antenna is the capability of an antenna with which electromagnetic energy is focused in a specific direction, and accordingly, the directionality of an antenna is defined as the ratio of uniform radiation intensity in every direction to radiation intensity in a given direction, which has a direct relationship to a radiation pattern.

Thirdly, an antenna gain is defined as the ratio of an isotropic pattern to relative intensity with respect to the direction of a maximum electric field.

The above-mentioned performance of the antenna is described as the important characteristics of a broadcasting and communication antenna or data transmission antenna.

On the other hand, an antenna factor is described as an important characteristic of an antenna for measuring electromagnetic interference EMI or effective isotropic radiated power EIRP of radio equipment.

The antenna factor is defined as the ratio of the electric field strength incident to an antenna to a voltage induced to an open circuit of the antenna.

The above-mentioned characteristics of the antenna have a given relationship to the antenna pattern measurement.

### DISCLOSURE

### Technical Problem

Accordingly, the present invention has been made in view of the above-mentioned problems occurring in the prior art, and it is an object of the present invention to provide an apparatus for measuring an antenna radiation pattern wherein when an antenna pattern is measured in an open area test site, an electromagnetic anechoic chamber, etc., if an antenna is rotated, in existing practices, the open front surface of the antenna or a maximum radiation surface (hereinafter, referred to as ‘look direction’) is deviated from a rotary shaft to cause an error in the pattern measurement, but according to the present invention, the look direction is positioned always at a radiation center shaft to allow the rotary shaft of the antenna and a vertical shaft in the look direction to correspond to each other, so that the vertical shaft in the look direction is not changed in position by rotation, thereby measuring the radiation pattern of the antenna easily and conveniently, without having a direction error, while allowing the antenna to rotate at a predetermined angle.

### Technical Solution

To accomplish the above-mentioned object, according to the present invention, there is provided an apparatus for measuring an antenna radiation pattern, the apparatus including: a lower bearing unit; a hollow mast disposed vertically with respect to the center of the lower bearing unit; a hollow vertical bar vertically adjustable in length in such a manner as to be slidingly inserted into the mast through the top end periphery of the mast; a goniometer coupled horizontally to the top periphery of the vertical bar; a horizontal shaft located above the goniometer and coupled horizontally to the top periphery of the vertical bar in such a manner as to be rotated forwardly and reversely; a first mounting unit vertically adjustable in length in such a manner as to be slidingly inserted into the vertical bar through the top end periphery of the vertical bar, an antenna being mounted on the top surface thereof; a second mounting unit having a vertical shaft penetratedly coupled vertically to one end of the horizontal shaft and an antenna fixing jig disposed on top of the vertical shaft; and a support unit having one end coupled to the horizontal shaft and the other end coupled to the outer periphery of the mast.

According to the present invention, desirably, the lower bearing unit includes: a plate having a shape of a circle or polygon; a plurality of legs coupled to the underside of the plate in such a manner as to be arranged radially and having a caster mounted thereon; and a cylindrical housing disposed vertically on the center of the top surface of the plate and having a top surface opened to accommodate the mast therein.

According to the present invention, desirably, each leg has a plurality of holes formed spaced apart from each other at given intervals in a longitudinal direction thereof and fixing pins detachably coupled to the holes, so that through the detachable coupling of the fixing pins to the holes, the length of the leg is varied.

According to the present invention, desirably, each leg further includes a first knob bolt rotating forwardly and reversely in such a manner as to be penetrated vertically thereinto and a fixing plate disposed on the underside of the first knob bolt.

According to the present invention, desirably, the housing includes a second knob bolt penetratedly inserted thereinto through one side thereof, so that through the forward rotation of the second knob bolt, the mast is fixed to the housing in such a manner as to be inserted into the housing to a given depth.

According to the present invention, desirably, the mast includes at least one or more third knob bolts penetratedly inserted thereinto through one side thereof, so that through the forward rotation of the third knob bolts, the vertical bar is fixed to the mast in such a manner as to be inserted into the mast to a given depth.

According to the present invention, desirably, the vertical bar has a screw thread formed on the upper side of the outer peripheral surface thereof and a first nut, a second nut and a third nut coupled to the upper peripheral surface thereof, the first nut being located between the mast and the goniometer, the second nut being located between the goniometer and the horizontal shaft, and the third nut being located between the horizontal shaft and the first mounting unit.

According to the present invention, desirably, the horizontal shaft includes an indication pin penetratedly disposed into the center thereof and a moving hole formed in a longitudinal direction thereof, so that along the moving hole, the position of the vertical shaft and the top end position of the support unit are moved.

According to the present invention, desirably, the vertical shaft includes a screw thread formed on the center of the outer periphery thereof and a fourth nut and a fifth nut located up and down with respect to the horizontal shaft, so that through the coupling of the fourth nut and the fifth nut to the vertical shaft, the vertical shaft is fixed to the horizontal shaft.

According to the present invention, desirably, the antenna fixing jig includes an upper plate and a lower plate disposed up and down to face each other and having recesses formed on the center portions thereof and a pair of fixing bolts connecting the upper plate and the lower plate with each other.

According to the present invention, desirably, the first mounting unit includes: a joint open on top and underside thereof in such a manner as to allow the lower periphery thereof to be press-fitted to the top end periphery of the vertical bar to a given depth and to allow a mounting plate to be slidingly inserted thereinto through the open top thereof; and a fourth knob bolt penetratedly inserted into the joint through the outer periphery of the joint to fix the mounting plate to the joint.

According to the present invention, desirably, the goniometer is foldable in half on the center thereof.

According to the present invention, desirably, the support unit includes a first support and a second support arranged to face each other in a longitudinal direction thereof and a plurality of connection pins connecting the first support and the second support with each other, the first support having a concave hole formed in a longitudinal direction thereof, and the second support having a plurality of connection holes formed spaced apart from each other at given intervals in a longitudinal direction thereof, so that through the detachable mounting of the connection pins into the connection holes, the length of the support unit is varied.

### Advantageous Effects

According to the present invention, the apparatus for measuring an antenna radiation pattern is capable of manually rotating an antenna at a predetermined angle with respect to the center of the front side of an opening of the antenna through a vertical shaft thereof in an open area test site, an electromagnetic anechoic chamber, etc., while the shaft of a radiation surface of the antenna is not being rotated by the rotation of the antenna, thereby measuring the antenna radiation pattern easily and conveniently.

### DESCRIPTION OF DRAWINGS

The drawing attached to the present invention illustrates a preferred embodiment of the present invention so as to allow the detailed description of the present invention and the technical scope of the present invention to be more understood, and it should be therefore noted that the present invention is not interpreted with the limitation of the components shown in the drawing.

FIG. 1 is a perspective view showing an apparatus for measuring an antenna radiation pattern according to the present invention.

FIG. 2 is an exploded perspective view showing the apparatus for measuring an antenna radiation pattern according to the present invention.

FIG. 3 is a side view showing the apparatus for measuring an antenna radiation pattern according to the present invention.

FIG. 4 is a side view showing the apparatus for measuring an antenna radiation pattern according to the present invention, wherein a log periodic antenna is mounted.

FIG. 5 is a side view showing the apparatus for measuring an antenna radiation pattern according to the present invention, wherein a biconical antenna is mounted.

FIG. 6 is a side view showing the apparatus for measuring an antenna radiation pattern according to the present invention, wherein a horn antenna is mounted.

### BEST MODE FOR INVENTION

Hereinafter, an explanation on an apparatus for measuring an antenna radiation pattern according to the present invention will be in detail given with reference to the attached drawing.

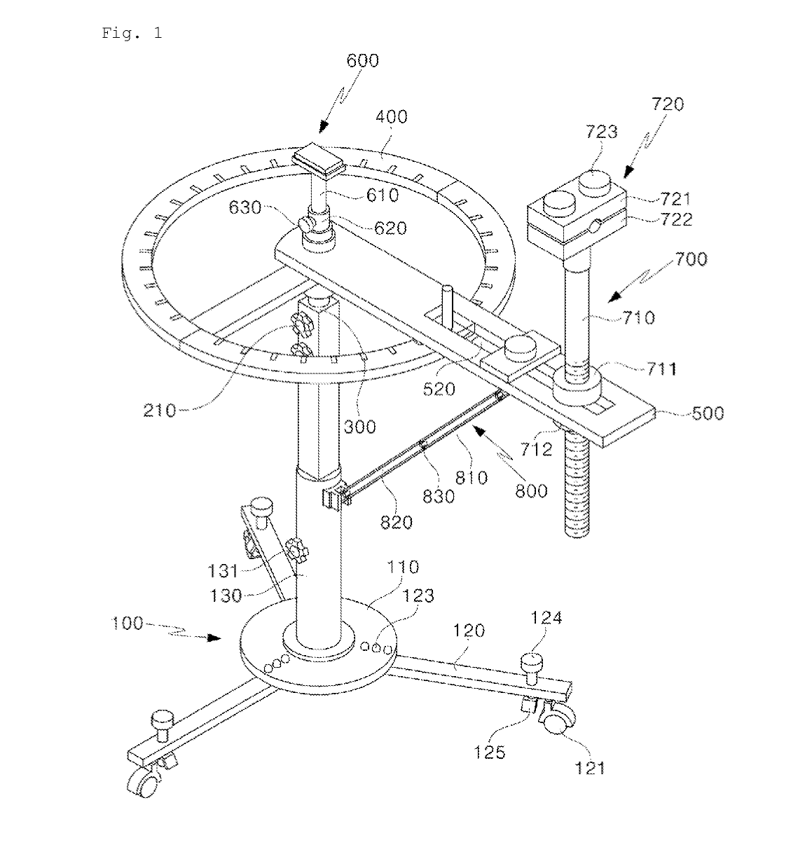

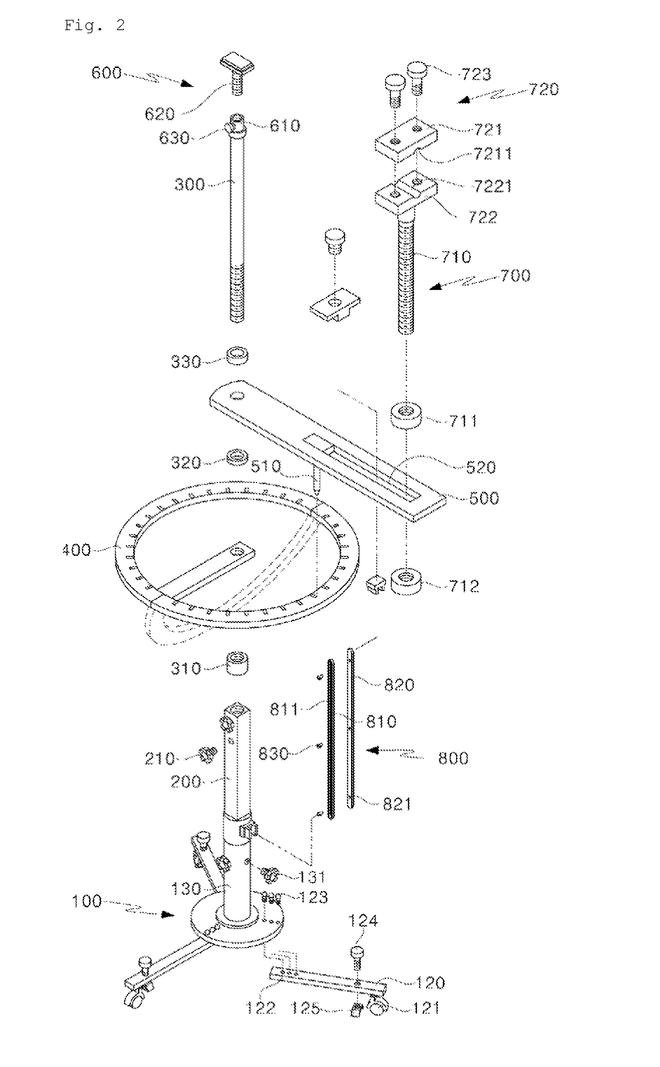

FIG. 1 is a perspective view showing an apparatus for measuring an antenna radiation pattern according to the present invention, and FIG. 2 is an exploded perspective view showing the apparatus for measuring an antenna radiation pattern according to the present invention.

Referring to FIGS. 1 and 2, an apparatus for measuring an antenna radiation pattern according to the present invention includes a lower bearing unit 100, a mast 200, a vertical bar 300, a goniometer 400, a horizontal shaft 500, a first mounting unit 600, a second mounting unit 600, and a support unit 800. The above-mentioned components will be in detailed explained below.

First, the components constituting the apparatus for measuring an antenna radiation pattern according to the present invention are desirably made of non-metallic materials such as FRP (Fiber glass Reinforced Plastic), Bakelite and MC, which are not under the influence of the reflection of a radio wave.

The lower bearing unit 100 includes a plate 110, legs 120, and a cylindrical housing 130.

The plate 110 has a shape of a circle or polygon, and the legs 120 are coupled to the underside of the plate 110 in such a manner as to be arranged radially around the plate 110 at intervals of about 120°. Each leg 120 has a caster 121 mounted thereon so as to easily move.

Further, each leg 120 has a plurality of holes 122 formed spaced apart from each other at given intervals in a longitudinal direction thereof and fixing pins 123 detachably coupled to the holes 122, so that through the detachable coupling of the fixing pins 123 to the holes 122, the length of the leg 120 can be varied.

So as to perform the fixation to the floor and horizontal adjustment, furthermore, the leg 120 includes a first knob bolt 124 rotating forwardly and reversely in such a manner as to be penetrated vertically thereinto and a fixing plate 125 disposed on the underside of the first knob bolt 124.

Further, the lower bearing unit 100 has the cylindrical housing 130 disposed vertically on the center of the top surface of the plate 110 and having a top surface opened to accommodate the mast 200 therein.

At this time, the housing 130 is separably mounted on the plate 110 so that it can be mounted on the plate 110 having a different shape.

The mast 200 desirably has a shape of a hollow square post and is disposed vertically with respect to the center of the lower bearing unit 100. In more detail, the mast 200 is inserted into the housing 130 through the top end periphery of the housing 130 and is adjustable up and down in length.

On the other hand, the housing 130 further includes a second knob bolt 131 penetratedly inserted thereinto through one side thereof, so that through the forward rotation of the second knob bolt 131, the mast 200 is fixed to the housing 130 in such a manner as to be inserted into the housing 130 to a given depth.

The vertical bar 300 is hollow and adjustable in length in a vertical direction in such a manner as to be slidingly inserted into the mast 200 from the top end periphery of the mast 200.

On the other hand, the mast 200 further includes at least one or more third knob bolts 210 penetratedly inserted thereinto through one side thereof, so that through the forward rotation of the third knob bolts 210, the vertical bar 300 is fixed to the mast 200 in such a manner as to be inserted into the mast 200 to a given depth.

The goniometer 400 has a shape of a circular plate with 360-degree scales marked thereon to indicate directions and is also foldable in half to prevent the radio wave transmitted from being reflected.

The horizontal shaft 500 is located above the goniometer 400 and coupled horizontally to the upper periphery of the vertical bar 300 in such a manner as to be rotatable forwardly and reversibly.

In this case, the vertical bar 300 has a screw thread formed on the upper side of the outer peripheral surface thereof and a first nut 310, a second nut 320 and a third nut 330 coupled to the upper peripheral surface thereof. The first nut 310 is located between the mast 200 and the goniometer 400, the second nut 320 between the goniometer 400 and the horizontal shaft 500, and the third nut 330 between the horizontal shaft 500 and the first mounting unit 600.

That is, if the second nut 320 and the third nut 330 are strongly rotated with respect to the vertical bar 300, the horizontal shaft 500 maintains a given angle at a given height, while being rotatable forwardly and reversibly.

The first mounting unit 600 is vertically adjustable in length in such a manner as to be slidingly inserted into the vertical bar 300 through the top end periphery of the vertical bar 300, and an antenna is mounted on top of the first mounting unit 600.

At this time, the first mounting unit 600 is open on top and underside thereof in such a manner as to allow the lower periphery thereof to be press-fitted to the top end periphery of the vertical bar 300 to a given depth.

Further, the first mounting unit 600 includes a joint 620 having a mounting plate 610 slidingly inserted thereinto through the open top thereof and a fourth knob bolt 630 penetratedly inserted into the joint 620 through the outer periphery of the joint 620 to fix the mounting plate 610 to the joint 620. In this case, the mounting plate 610 is movable up and down in the interior of the joint 620, so that through the forward and reverse rotation of the fourth knob bolt 630, the mounting plate 610 is fixedly disposed on the interior of the joint 620 to a given height.

The second mounting unit 700 includes a vertical shaft 710 and an antenna fixing jig 720. The vertical shaft 710 is penetratedly vertically into one end of the horizontal shaft 500 and coupled to the horizontal shaft 500.

Further, the antenna fixing jig 720 is located on top of the vertical shaft 710 and includes an upper plate 721 and a lower plate 722 disposed to face each other and having recesses 7211 and 7221 formed on the center portions thereof and a pair of fixing bolts 723 connecting the upper plate 721 and the lower plate 722 with each other and fixing one side of the antenna thereto.

In this case, the vertical shaft 710 has a screw thread formed on the center of the outer periphery thereof, and a fourth nut 711 and a fifth nut 712 are located up and down with respect to the horizontal shaft 500, so that through the coupling of the fourth nut 711 and the fifth nut 712 to the vertical shaft 710, the vertical shaft 710 is fixed to the horizontal shaft 500, and further, the vertical shaft 710 is adjustable in height up and down with respect to the horizontal shaft 500.

The support unit 800 has one end coupled to the horizontal shaft 500 and the other end coupled to the outer periphery of the mast 200.

At this time, the support unit 800 includes a first support 810 and a second support 820 arranged to face each other in a longitudinal direction thereof and a plurality of connection pins 830 connecting the first support 810 and the second support 820 with each other.

In this case, the first support 810 has a concave hole 811 formed in a longitudinal direction thereof, and the second support 820 has a plurality of connection holes 821 spaced apart from each other at given intervals in a longitudinal direction thereof, so that through the detachable mounting of the connection pins 830 into the connection holes 821, the support unit 800 can be varied in length.

On the other hand, the horizontal shaft 500 further includes an indication pin 510 penetratedly disposed into the center thereof, so that through the indication pin 510, the direction of the goniometer 400 can be accurately read.

Further, the horizontal shaft 500 includes a moving hole 520 formed in a longitudinal direction thereof, so that along the moving hole 520, the position of the vertical shaft 710 and the top end position of the support unit 800 can be moved.

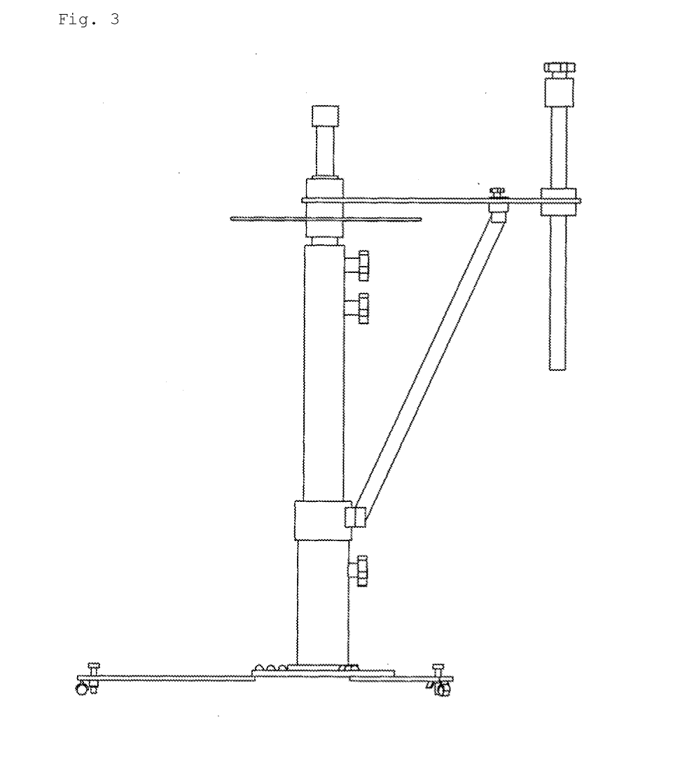

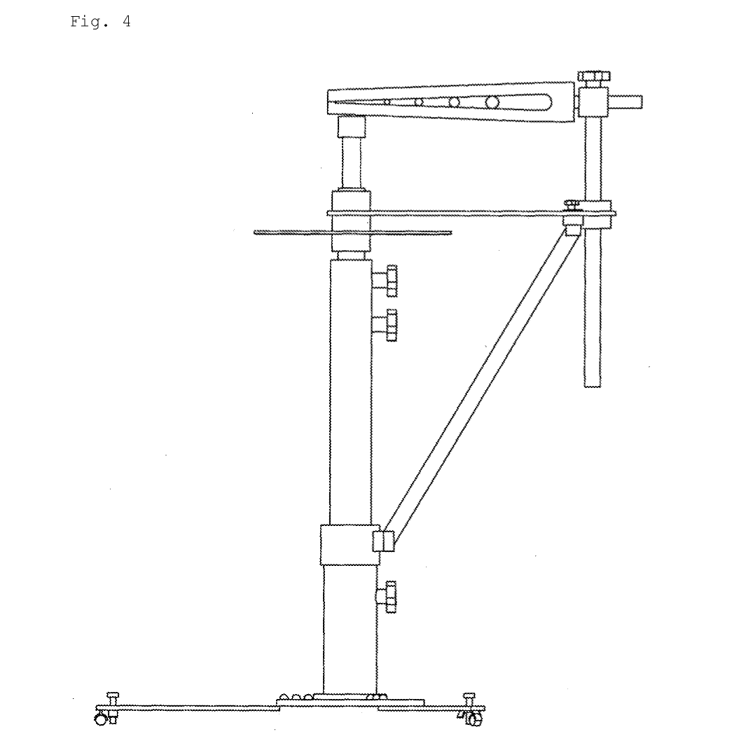

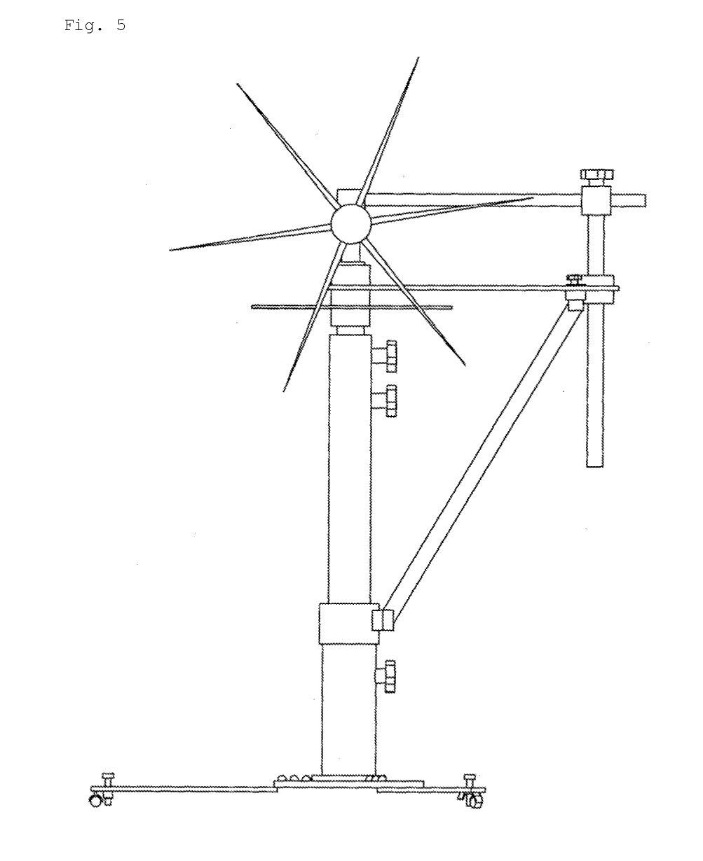

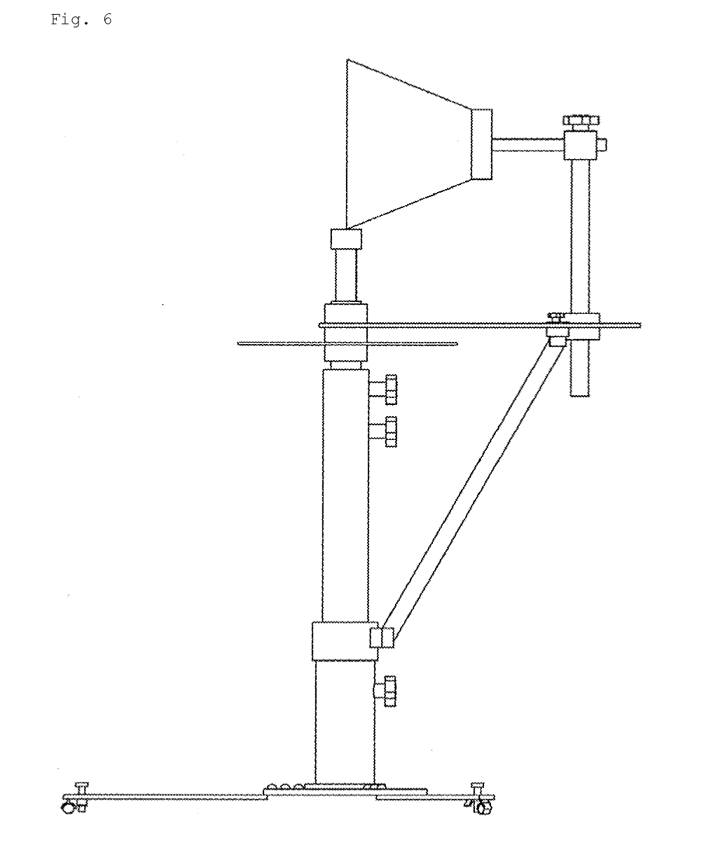

FIG. 3 is a side view showing the apparatus for measuring an antenna radiation pattern according to the present invention, FIG. 4 is a side view showing the apparatus for measuring an antenna radiation pattern according to the present invention, wherein a log periodic antenna is mounted, FIG. 5 is a side view showing the apparatus for measuring an antenna radiation pattern according to the present invention, wherein a biconical antenna is mounted, and FIG. 6 is a side view showing the apparatus for measuring an antenna radiation pattern according to the present invention, wherein a horn antenna is mounted.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. An apparatus for measuring an antenna radiation pattern, the apparatus comprising:
a lower bearing unit 100;
a hollow mast 200 disposed vertically with respect to the center of the lower bearing unit 100;
a hollow vertical bar 300 vertically adjustable in length in such a manner as to be slidingly inserted into the mast 200 through the top end periphery of the mast 200;
a goniometer 400 coupled horizontally to the top periphery of the vertical bar 300;
a horizontal shaft 500 located above the goniometer 400 and coupled horizontally to the top periphery of the vertical bar 300 in such a manner as to be rotated forwardly and reversely;
a first mounting unit 600 vertically adjustable in length in such a manner as to be slidingly inserted into the vertical bar 300 through the top end periphery of the vertical bar 300, an antenna being mounted on the top surface thereof;
a second mounting unit 700 having a vertical shaft 710 penetratedly coupled vertically to one end of the horizontal shaft 500 and an antenna fixing jig 720 disposed on top of the vertical shaft 710; and
a support unit 800 having one end coupled to the horizontal shaft 500 and the other end coupled to the outer periphery of the mast 200.

2. The apparatus according to claim 1, wherein the lower bearing unit 100 comprises:
a plate 110 having a shape of a circle or polygon;
a plurality of legs 120 coupled to the underside of the plate 110 in such a manner as to be arranged radially and having a caster 121 mounted thereon; and
a cylindrical housing 130 disposed vertically on the center of the top surface of the plate 110 and having a top surface opened to accommodate the mast 200 therein.

3. The apparatus according to claim 2, wherein each leg 120 has a plurality of holes 122 formed spaced apart from each other at given intervals in a longitudinal direction thereof and fixing pins 123 detachably coupled to the holes 122, so that through the detachable coupling of the fixing pins 123 to the holes 122, the length of the leg 120 is varied.

4. The apparatus according to claim 3, wherein each leg 120 further comprises a first knob bolt 124 rotating forwardly and reversely in such a manner as to be penetrated vertically thereinto and a fixing plate 125 disposed on the underside of the first knob bolt 124.

5. The apparatus according to claim 2, wherein the housing 130 comprises a second knob bolt 131 penetratedly inserted thereinto through one side thereof, so that through the forward rotation of the second knob bolt 131, the mast 200 is fixed to the housing 130 in such a manner as to be inserted into the housing 130 to a given depth.

6. The apparatus according to claim 1, wherein the mast 200 comprises at least one or more third knob bolts 210 penetratedly inserted thereinto through one side thereof, so that through the forward rotation of the third knob bolts 210, the vertical bar 300 is fixed to the mast 200 in such a manner as to be inserted into the mast 200 to a given depth.

7. The apparatus according to claim 1, wherein the vertical bar 300 has a screw thread formed on the upper side of the outer peripheral surface thereof and a first nut 310, a second nut 320 and a third nut 330 coupled to the upper peripheral surface thereof, the first nut 310 being located between the mast 200 and the goniometer 400, the second nut 320 being located between the goniometer 400 and the horizontal shaft 500, and the third nut 330 being located between the horizontal shaft 500 and the first mounting unit 600.

8. The apparatus according to claim 1, wherein the horizontal shaft 500 comprises an indication pin 510 penetratedly disposed into the center thereof and a moving hole 520 formed in a longitudinal direction thereof, so that along the moving hole 520, the position of the vertical shaft 710 and the top end position of the support unit 800 are moved.

9. The apparatus according to claim 8, wherein the vertical shaft 710 comprises a screw thread formed on the center of the outer periphery thereof and a fourth nut 711 and a fifth nut 712 located up and down with respect to the horizontal shaft 500, so that through the coupling of the fourth nut 711 and the fifth nut 712 to the vertical shaft 710, the vertical shaft 710 is fixed to the horizontal shaft 500.

10. The apparatus according to claim 1, wherein the antenna fixing jig 720 comprises an upper plate 721 and a lower plate 722 disposed up and down to face each other and having recesses 7211 and 7221 formed on the center portions thereof and a pair of fixing bolts 723 connecting the upper plate 721 and the lower plate 722 with each other.

11. The apparatus according to claim 1, wherein the first mounting unit 600 comprises: a joint 620 open on top and underside thereof in such a manner as to allow the lower periphery thereof to be press-fitted to the top end periphery of the vertical bar 300 to a given depth and to allow a mounting plate 610 to be slidingly inserted thereinto through the open top thereof; and a fourth knob bolt 630 penetratedly inserted into the joint 620 through the outer periphery of the joint 620 to fix the mounting plate 610 to the joint 620.

12. The apparatus according to claim 1, wherein the goniometer 400 is foldable in half on the center thereof.

13. The apparatus according to claim 1, wherein the support unit 800 comprises a first support 810 and a second support 820 arranged to face each other in a longitudinal direction thereof and a plurality of connection pins 830 connecting the first support 810 and the second support 820 with each other, the first support 810 having a concave hole 811 formed in a longitudinal direction thereof, and the second support 820 having a plurality of connection holes 821 spaced apart from each other at given intervals in a longitudinal direction thereof, so that through the detachable mounting of the connection pins 830 into the connection holes 821, the length of the support unit 800 is varied.
